(19) United States
(12) Patent Application Publication
(10) Pub. No.: US 2025/0074836 A1
(43) Pub. Date: Mar. 6, 2025

(54) STRUCTURAL MEMBER

(71) Applicant: TOTO LTD., Fukuoka (JP)

(72) Inventors: Tatsuya KOGA, Fukuoka (JP); Nobutomo OTSUKA, Fukuoka (JP); Yasutaka NITTA, Fukuoka (JP)

(73) Assignee: TOTO LTD., Fukuoka (JP)

(21) Appl. No.: 18/806,228

(22) Filed: Aug. 15, 2024

(30) Foreign Application Priority Data
Aug. 29, 2023 (JP) 2023-138937

(51) Int. Cl. C04B 41/45; C04B 41/52

(52) U.S. Cl. CPC C04B 41/4529; C04B 41/4543; C04B 41/52

(57) ABSTRACT

A structural member 10 includes a base material 100 which is a ceramic, an underlayer 200 covering a surface S1 of the base material 100, and a protective film 300 covering a surface S2 of the underlayer 200. An orientation of each crystallite 210 on a surface S2 of the underlayer 200 on the protective film 300 side is not aligned and is irregular.

### CROSS-REFERENCE TO RELATED APPLICATION

This application is based upon and claims the benefit of priority from Japanese Patent Application No. 2023-138937 filed on Aug. 29, 2023, the entire contents of which are incorporated herein by reference.

### BACKGROUND

### Field of the Invention

The present invention relates to a structural member.

### Description of the Related Art

Structural members having a protective film on a surface of a base material are used in various fields such as semiconductor manufacturing apparatus. For example, as described in Japanese Patent Laid-Open No. 2007-321183, in a semiconductor manufacturing apparatus, a protective film is formed on a surface of a base material constituting an inner wall of a chamber in order to protect the base material from plasma. As the base material, for example, a ceramic such as alumina is used. As the protective film, for example, yttria, yttrium fluoride, or the like is used. Various deposition methods can be used to form the protective film on a surface of the base material, such as an aerosol deposition method and a physical vapor deposition (PVD) method.

### SUMMARY

On a surface of a base material composed of a ceramic material, a plurality of crystallites are exposed, and a protective film is formed so as to cover them. The size and orientation of each crystallite on the surface of the base material, and the like vary depending on the calcination conditions of the base material or the like.

The present inventors have found that orientations of crystallites on a base material surface have a significant effect on durability of a protective film covering them. Specifically, when crystallites are oriented in a specific direction, durability of a protective film deposited directly above the crystallites has been found to be significantly lowered. The “specific direction” in the above, i.e., orientations of the crystallites such that the durability of the protective film formed directly above them is lowered, is also referred to as the “specific direction” below for convenience of explanation.

In order to improve the durability of the entire protective film, the orientations of all the crystallites on a surface of a base material are preferably different from the specific direction described above. However, it is difficult to adjust the crystallites for their orientations on the entire surface of the base material, which is a large member.

The present invention was made in view of these problems, and an object of the present invention is to provide a structural member having high durability against plasma.

In order to solve the above problem, the structural member according to the present invention includes a base material which is a ceramic, an underlayer covering a surface of the base material, and a protective film covering a surface of the underlayer. An orientation of each crystallite on a surface of the underlayer on the protective film side is not aligned and is irregular.

Such a structural member is formed so that the protective film does not directly cover the surface of the base material, but covers the surface of the underlayer formed between the base material and the protective film. On the surface of the underlayer, the orientation of each crystallite is not aligned and irregular. Therefore, even when a large number of crystallites are oriented in the specific direction on the surface of the base material, the durability of the protective film will not be lowered due to this effect.

Incidentally, a crystallite oriented in the “specific direction” can be present in a portion of the underlayer, but is present only locally, so that a protective film with low durability against plasma will not be formed over a wide region of the film. For example, making a size of crystallite in the underlayer small enables an influence of the crystallite oriented in the specific direction to be minimized to the extent that the influence can be negligible.

According to the present invention, a structural member having high durability against plasma can be provided.

### BRIEF DESCRIPTION OF THE DRAWINGS

FIG. 1 shows a schematical diagram of a cross-section of the structural member according to the present embodiment;

FIG. 2 shows a schematical diagram of arrangement and the like of crystallites on a surface of an underlayer;

FIG. 3 shows a schematical diagram of arrangement and the like of crystallites on a surface of a base material;

FIG. 4A and FIG. 4B show diagrams for explaining an effect of having arranged an underlayer; and

FIGS. 5A to 5C show a diagram for explaining the method for producing a structural member according to the present embodiment.

### DETAILED DESCRIPTION

The present embodiment will be described by referring to the attached drawings. In order to facilitate understanding of the description, an identical constituent is indicated with the same sign as far as possible in each drawing, and duplicated explanations will be omitted.

A structural member 10 according to the present embodiment is used as a member constituting an inner wall of a processing chamber in a semiconductor manufacturing apparatus (not shown), for example, such as a plasma etching apparatus. Note, however, that the application of such structural member 10 is only an example, and should not be limited to the semiconductor manufacturing apparatus.

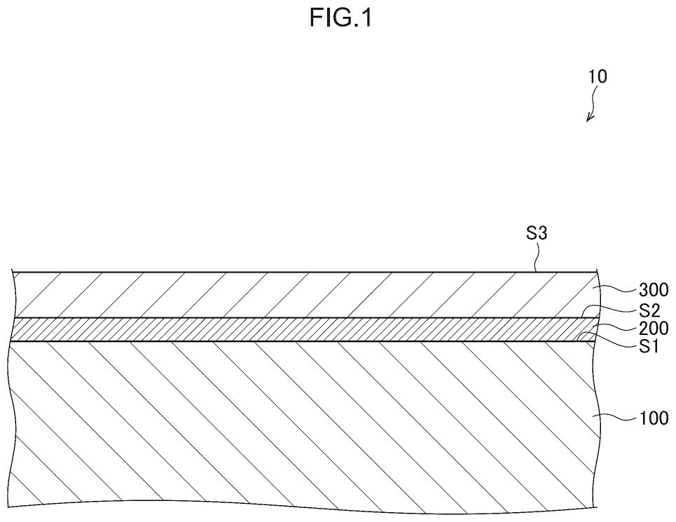

As shown in FIG. 1, the structural member 10 includes a base material 100, an underlayer 200, and a protective film 300. In a plasma etching apparatus and the like, a surface S3 of the protective film 300 is exposed toward a space in the chamber. The protective film 300 is arranged for the purpose of protecting a surface S1 of the base material 100 from plasma.

The base material 100 is a member that mostly occupies the entire structural member 10. In the present embodiment, the base material 100 is composed of a sintered ceramic body containing high-purity aluminum oxide (Al2O3), but may be made of a different type of ceramic. The surface S1 of the base material 100 is a flat surface in the present embodiment, but the surface S1 may have a convex and concave structure, a slope, or the like.

The underlayer 200 is a layer formed so as to cover the surface S1 of the base material 100. The protective film 300, which will be described next, is formed so as not to directly cover the surface S1 of the base material 100 but to cover a surface S2 of the underlayer 200. The underlayer 200 is a layer containing polycrystalline yttria (Y2O3) and is formed using an aerosol deposition method. The reason for having interposed the underlayer 200 between the base material 100 and the protective film 300 will be explained below.

As described above, the protective film 300 is a film formed to protect the base material 100 from plasma. The protective film 300 is formed so as to cover the entire surface S2 of the underlayer 200. The protective film 300 is a film containing polycrystalline yttria (Y2O3) and is formed using a physical vapor deposition (PVD) method. A thickness of the protective film 300 is appropriately set depending on a period of time required to maintain durability against plasma, and the like. In the present embodiment, the thickness of the protective film 300 is 10 μm. The protective film 300 and the underlayer 200 may be formed using the same material as each other as in the present embodiment, or they may be formed using different materials from each other.

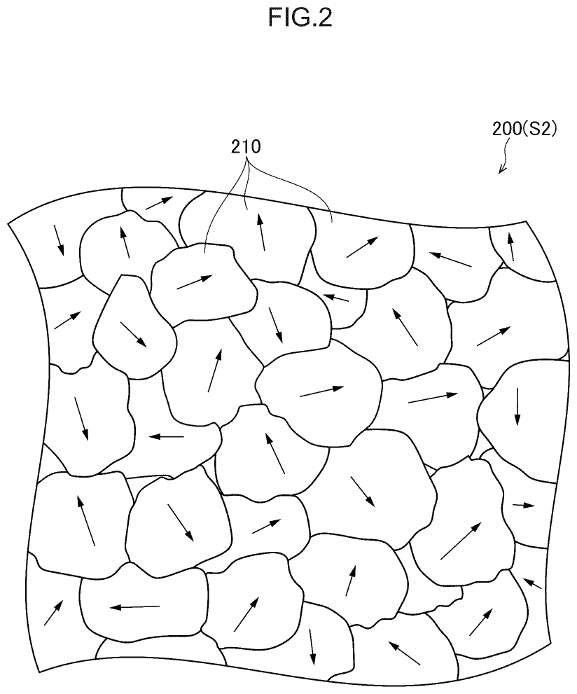

FIG. 2 shows a schematical diagram of the surface S2 of the underlayer 200, which was viewed from a direction perpendicular thereto. On the surface S2, a plurality of crystallites 210 constituting the underlayer 200 are arranged. The protective film 300 is formed so as to cover the surface S2 in FIG. 2 from the front side of the paper. In FIG. 2, the arrow drawn above each of the crystallites 210 represents the orientation of the crystallite 210. The “orientation” is an orientation that is defined individually for each crystallite 210, for example, as orientation such that the Miller index (direction index) is a specific value.

As is well known, in an aerosol deposition method, microparticles that are materials for the underlayer 200, are dispersed in gas to form an “aerosol,” which is then injected and brought into collision toward the surface S1 of the base material 100. On the surface S1, deformation and crushing of the microparticles result from the impact of collision, thereby allowing the microparticles to be gradually deposited as the underlayer 200 while bonded with each other. As a result of being formed in this manner, the orientation of each of the crystallites 210 on the surface S2 of the underlayer 200 is irregular without being aligned in a specific direction.

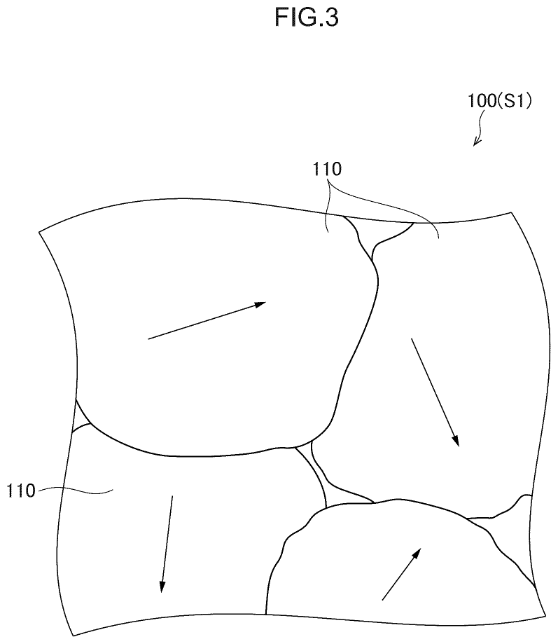

FIG. 3 shows a schematic diagram depicting the surface S1 of the base material 100, which was viewed from a direction perpendicular thereto. A plurality of crystallites 110 constituting the base material 100 are arranged on the surface S1. The underlayer 200 is formed so as to cover the surface S1 in FIG. 3 from the front side of the paper. In FIG. 3, the arrow representing the orientation of the crystallite 110 is also depicted above each crystallite 110, as in FIG. 2. The definition of the “orientation” is the same as for the crystallite 210. In the present embodiment, the orientation of crystallite 110 on the surface S1 is also irregular without being aligned in a specific direction. Instead of such an embodiment, an embodiment such that the orientation of the crystallite 110 is aligned in one direction, may be adopted.

As is clear from comparing FIG. 2 and FIG. 3, an average crystallite size in the underlayer 200 (FIG. 2) is smaller than that of the base material 100 (FIG. 3). The “average crystallite size” is an average value of the diameters of a plurality of crystallites that are observed in a cross-section of each member (underlayer 200 or base material 100) when cut.

The crystallite size can be calculated, for example, by photographing a transmission electron microscope (TEM) image at a magnification of 400,000 times or more and obtaining an average value of the diameters of 15 approximately-circular crystallites in the image. In this case, a sample thickness made sufficiently thin (about 30 nm) upon focused ion beam (FIB) processing, enables identification of crystallite more clearly. The magnification for photographing can be selected as appropriate in the range of 400,000 times or more.

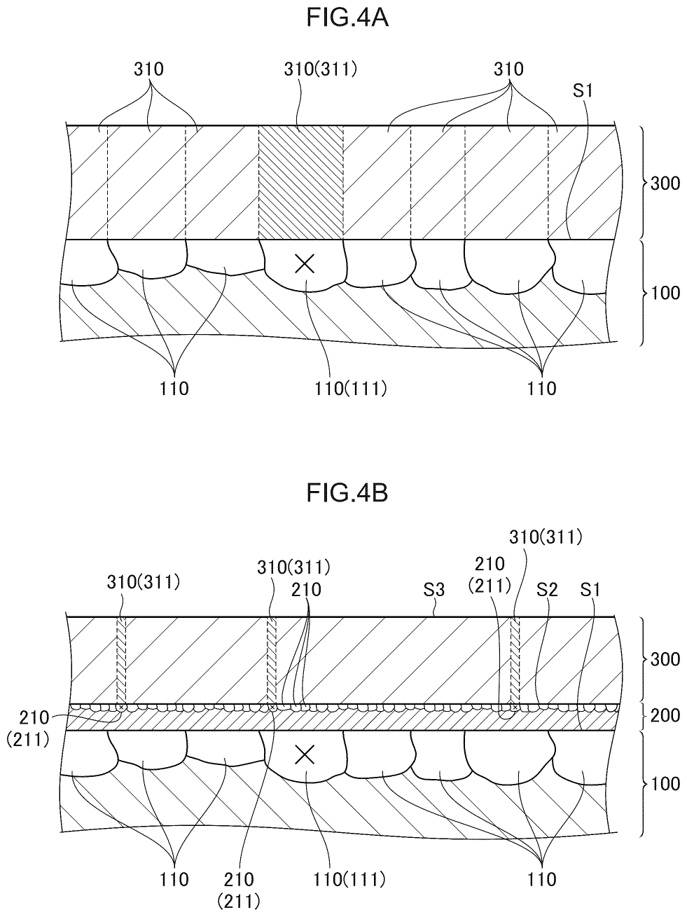

The reason for having interposed the underlayer 200 between the base material 100 and the protective film 300 will be described. FIG. 4A shows an example in which the protective film 300 was directly formed on the surface S1 of the base material 100 without interposition of the underlayer 200, as a comparative example of the present embodiment. In this figure, cross-sections of the crystallites 110 are depicted only in a portion of the base material 100 in the vicinity of the surface S1, and the crystallites 110 are omitted in the inner (lower side in the figure) portion than the vicinity of the surface S1.

The protective film 300 is formed so as to cover each crystallite 110 exposed on the surface S1. The entire portion of the protective film 300 that covers one (i.e., common) crystallite 110 from directly above is hereinafter defined as a “small region 310”. The protective film 300 will be divided into a plurality of small regions 310 for each crystallite 110 present on the surface S1. In FIG. 4A, the boundaries of the small regions 310 adjacent to each other are indicated by dotted lines.

The protective film 300 formed using a physical vapor deposition method grows while being influenced by the orientation of the crystallite 110 directly below the protective film 300, i.e., the crystallite 110 that is the starting point of film deposition. Therefore, the nature of the protective film 300 is not uniform over the entire protective film 300, but differs for each small region 310.

The present inventors have found as a result of diligent research on the relationship between an orientation of the crystallite 110 and durability of the protective film 300 formed directly above the crystallite 110 that the orientation of the crystallite 110 on the base material surface has a significant effect on the durability of the protective film 300 against plasma. Specifically, when the crystallite 110 is oriented in the specific direction, the durability of the protective film deposited directly above the crystallite 110 was found to be significantly lowered. The “specific direction” in the above described, i.e., orientation of the crystallite 110 such that the durability of the protective film formed directly above the crystallite was lowered, is also referred to as the “specific direction” below for convenience of explanation. The orientation of the crystallite 210 is defined in the same manner.

In FIG. 4A, the crystallite 110 with orientation in the specific direction is marked with an “X”. Such a crystallite 110 is also particularly referred to as a “crystallite 111” below. The small region 310 directly above the crystallite 111 is also particularly referred to as the “small region 311” below.

The small region 311 is a portion where durability against plasma is significantly lowered due to an effect of the orientation of the crystallite 111. The shape of the small region 311 viewed from the top is generally the same as that of the crystallite 111 directly below the small region. Therefore, when the crystallite 111 is large, the range of the small region 311 with low durability also becomes large, thereby lowering the durability of the protective film 300 as a whole.

There can occur a case where the orientations of the crystallites 110 are aligned in a specific direction. In this case, almost all of the crystallites 110 become the crystallites 111, and the protective films 300 on top of them all become the small regions 311. Therefore, regardless of size of the crystallite 110, the durability of the protective film 300 as a whole will be lowered.

In order to improve the durability of the protective film 300, the orientations of all the crystallites 110 are preferably different from the specific direction. However, it is often difficult to adjust the crystallites 110 for their orientations on the entire surface of the base material 100 which is a large member.

Therefore, in the present embodiment, the durability of the protective film 300 is improved by interposing the underlayer 200 between the base material 100 and the protective film 300 and devising orientations of the crystallites 210 in the underlayer 200, or the like.

FIG. 4B schematically depicts a configuration of the structural member 10 according to the present embodiment in the same manner as in FIG. 4A. In the example of FIG. 4B, the surface S1 of the base material 100, which is the same as that in the example of FIG. 4A, is covered by the underlayer 200. In FIG. 4B, cross-sections of the crystallites 210 are depicted only in a portion of the underlayer 200 in the vicinity of the surface S2, and the crystallite 210 is omitted in the inner (lower side in the figure) portion than the vicinity of the surface S2.

In, FIG. 4B, the crystallite 210 with orientation in the specific direction, is marked with an “X”. Such a crystallite 210 is also particularly referred to as a “crystallite 211” below. The protective film 300 in FIG. 4B will be divided into a plurality of small regions 310 for each crystallite 210 on the surface S2. The small region 310 directly above crystallite 211 will also be a “small region 311” with lower durability. For convenience of illustration, only the small region 311 of the plurality of small regions 310 is shown in FIG. 4B.

As described above, on the surface S2 of the underlayer 200, the orientations of the respective crystallites 210 are not aligned and are irregular. Therefore, even when a large number of crystallites 110 are oriented in the specific direction on the surface S1 of the base material 100, the durability of the protective film 300 will not be lowered due to this effect. There can be present the crystallite 211 oriented in the “specific direction” in a portion of the underlayer 200, but is present only locally, so that the small region 311 with low durability against plasma will not be widely formed directly above the underlayer 200.

Furthermore, in the present embodiment, the average crystallite size in the underlayer 200 is smaller than that in the base material 100. The crystallite 211 oriented in the specific direction becomes smaller, so that the small region 311 directly above it also becomes smaller, as a result of which the effect on the durability of the protective film 300 as a whole is kept negligibly small.

Since the underlayer 200 is provided to adjust the small region 311 for its distribution and size in the protective film 300, the underlayer 200 may only have a minimum thickness to the extent that it can withstand formation of the protective film 300. For this reason, the underlayer 200 is thinner than the protective film 300, and in the present embodiment, the thickness is 5 μm or less. The thickness of the underlayer 200 made to a minimum thickness enables time and cost required for deposition of the underlayer 200 to be minimized.

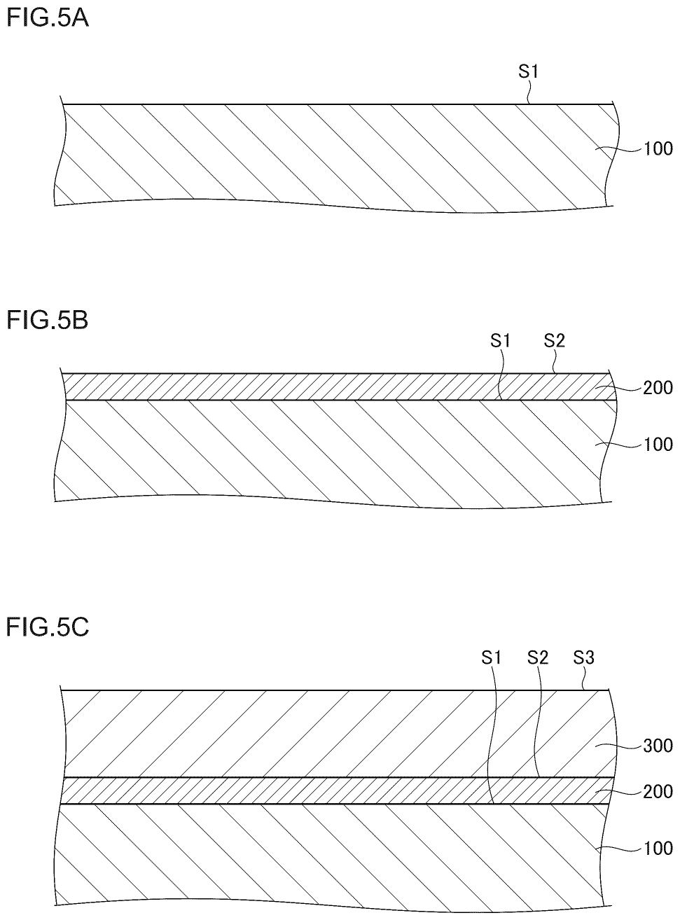

A method for producing the structural member 10 will be described with reference to FIG. 5A to FIG. 5C. As shown in FIG. 5A, first, the base material 100 is provided. It is preferable that the surface S1 of the base material 100 has been preliminarily adjusted for surface roughness thereof, and the like to the extent that the underlayer 200 can be stably formed thereafter.

Subsequently, as shown in FIG. 5B, the underlayer 200 is then formed so as to cover the surface S1 of the base material 100. As described above, in the present embodiment, the underlayer 200 is formed using the aerosol deposition method. As a result, each of the crystallites 210 of the underlayer 200 is formed in such a way that the orientations of the crystallites 210 are not aligned and irregular.

Incidentally, the underlayer 200 may be formed by other methods, provided that the orientations of the crystallites 210 can be made irregular. For example, the underlayer 200 may be formed by PVD or CVD. A method may also be employed, the method for arranging a platy temporarily calcinated body so as to cover the surface S1 of the base material 100, then heating the entire temporarily calcinated body and sintering it to form the underlayer 200.

It is preferable that the surface S2 of the underlayer 200 has been preliminarily adjusted for surface roughness thereof, and the like to the extent that the protective film 300 can be stably formed thereafter.

Subsequently, as shown in FIG. 5C, the protective film 300 is formed so as to cover the surface S2 of the underlayer 200. As described before, in the present embodiment, the protective film 300 is formed using a physical vapor deposition (PVD) method. Each portion of the protective film 300 will grow under the influence of the surface S2 of the underlayer 200 directly below the protective film 300. As described so far, in the protective film 300, there can be present small regions 311 with low durability against plasma, which have small areas and are dispersedly arranged, thereby ensuring the durability of the protective film 300 sufficiently.

The protective film 300 may be formed by a method other than the physical vapor deposition method. For example, the protective film 300 may be formed by a method such as CVD or ALD. However, when the protective film 300 is formed using the physical vapor deposition method as in the present embodiment, a dense protective film 300 can be formed at relatively low costs, which is preferable.

So far, the present embodiments have been described with reference to specific examples. However, the present disclosure is not limited to these specific examples. Design changes appropriately made to these specific examples by those skilled in the art are also included in the scope of the present disclosure as long as they include the features of the present disclosure. Each element included in each of the aforementioned specific examples, as well as their arrangement, conditions, shapes, and the like, are not limited to those exemplified, and can be appropriately changed. Each element included in each of the aforementioned specific examples can be appropriately combined as long as no technical inconsistency thereof results.

What is claimed is:

1. A structural member comprising a base material which is a ceramic, an underlayer covering a surface of the base material, and a protective film covering a surface of the underlayer,
wherein an orientation of each crystallite on a surface of the underlayer on the protective film side is not aligned and is irregular.

2. The structural member according to claim 1, wherein an average crystallite size in the underlayer is smaller than an average crystallite size in the base material.

3. The structural member according to claim 1, wherein the underlayer is thinner than the protective film.

4. The structural member according to claim 1, wherein the underlayer is formed by an aerosol deposition method.

5. The structural member according to claim 1, wherein the protective film is formed by a physical vapor deposition method.
